(19) United States
(12) Patent Application Publication
(10) Pub. No.: US 2014/0332978 A1
(43) Pub. Date: Nov. 13, 2014

(54) OPTICAL WIRING SUBSTRATE, MANUFACTURING METHOD OF OPTICAL WIRING SUBSTRATE AND OPTICAL MODULE

(71) Applicant: Hitachi Metals, Ltd., Tokyo (JP)

(72) Inventors: Hiroki YASUDA, Mito (JP); Kouki HIRANO, Hitachinaka (JP); Hiroshi ISHIKAWA, Hitachi (JP)

(73) Assignee: Hitachi Metals, Ltd., Tokyo (JP)

(21) Appl. No.: 14/250,523

(22) Filed: Apr. 11, 2014

(30) Foreign Application Priority Data
May 7, 2013 (JP) 2013-097754

(51) Int. Cl. H01L 23/522; H01L 21/768

(52) U.S. Cl. CPC H01L 23/5226; H01L 21/76877
USPC 257/774; 438/667

(57) ABSTRACT

An optical wiring substrate includes a first conductor layer including a metal, a second conductor layer including a metal and arranged parallel to the first conductor layer, an insulation layer disposed to insulate the first conductor layer from the second conductor layer, and an electronic component including a photoelectric conversion element mounted on the substrate, and a via hole formed in the second conductor layer and the insulation layer so as to pass through the second conductor layer and the insulation layer in a thickness direction thereof, the via hole including an inner surface plated with a metal. The via hole is configured such that at least a part of a bottom surface thereof blocked by the first conductor layer is arranged in a plan view so as to overlap with an arrangement position of a pad of the electronic component that is mounted on the first conductor layer.

The present application is based on Japanese patent application No. 2013-097754 filed on May 7, 2013, the entire contents of which are incorporated herein by reference.

### BACKGROUND OF THE INVENTION

1. Field of the Invention

This invention relates to an optical wiring substrate with wiring patterns formed thereon, a manufacturing method of the optical wiring substrate and an optical module using the optical wiring substrate.

2. Description of the Related Art

An optical module in which electric wirings are patterned and a photoelectric conversion element is mounted is known (for example, JP-A-2009-151072).

The optical module described in JP-A-2009-151072 includes a substrate comprised of an insulating resin layer and a metal layer formed on the surface of the insulating resin layer, a photoelectric conversion element mounted on the substrate by flip-chip mounting, a semiconductor circuit element connected to the substrate by wire bonding, an optical waveguide optically connected to an optical fiber, and an optical signal path conversion component in which a reflecting surface is formed, the reflecting surface being configured to reflect a light that propagates an inner portion of the optical fiber and the optical waveguide. The photoelectric conversion element is configured such that the light-receiving and emitting surface faces the reflecting surface of the optical signal path conversion component.

### SUMMARY OF THE INVENTION

Recently, in association with density growth of components in an electronic device such as an information processing device, a communicating device, an optical module is also needed to be reduced in size. However, if the optical module is reduced in size, radiation surface area in the optical wiring substrate becomes small, thus it becomes difficult to radiate heat emitted from the electronic components mounted in the optical wiring substrate. There is a possibility of damaging the electronic components due to temperature increase in the optical module.

It is an object of the invention to provide an optical wiring substrate that is capable of enhancing heat radiation and facilitating arrangement of wiring, as well as a manufacturing method of the optical wiring substrate and an optical module using the optical wiring substrate.

According to one embodiment of the invention, an optical wiring substrate comprises:

a first conductor layer comprising a metal;

a second conductor layer comprising a metal and arranged parallel to the first conductor layer;

an insulation layer disposed to insulate the first conductor layer from the second conductor layer; and

an electronic component including a photoelectric conversion element mounted on the substrate; and

a via hole formed in the second conductor layer and the insulation layer so as to pass through the second conductor layer and the insulation layer in a thickness direction thereof, the via hole comprising an inner surface plated with a metal,

wherein the via hole is configured such that at least a part of a bottom surface thereof blocked by the first conductor layer is arranged in a plan view so as to overlap with an arrangement position of a pad of the electronic component that is mounted on the first conductor layer.

According to another embodiment of the invention, an optical module comprises:

the optical wiring substrate as defined above; and

the electronic component.

According to another embodiment of the invention, a manufacturing method of the optical wiring substrate as defined above comprises:

forming the first conductor layer on a first principal surface of the insulation layer, and forming the second conductor layer on a second principal surface of the insulation layer;

removing a part of the first conductor layer so as to form a wiring pattern;

making a hole in the second conductor layer and the insulation layer over a whole thereof in a thickness direction so as to reach the first conductor layer; and

forming a plating layer on the inner surface of the hole made in the making of the hole and a front surface of the second conductor layer.

### Effects of the Invention

According to one embodiment of the invention, an optical wiring substrate can be provided that is capable of enhancing heat radiation and facilitating arrangement of wiring, as well as a manufacturing method of the optical wiring substrate and an optical module using the optical wiring substrate.

### BRIEF DESCRIPTION OF THE DRAWINGS

The preferred embodiments according to the invention will be explained below referring to the drawings, wherein:

FIG. 1 is a plan view schematically showing a configuration example of an optical wiring substrate and an optical module including the optical wiring substrate according to an embodiment of the invention;

FIG. 2 is a cross-sectional view taken along the line A-A in FIG. 1;

FIG. 3A is a cross-sectional view taken along the line B-B in FIG. 1;

FIG. 3B is a partial enlarged view of E part in FIG. 3A;

FIG. 4 is a cross-sectional view taken along the line D-D in FIG. 1;

FIG. 5 is a partial enlarged view of C part in FIG. 1; and

FIGS. 6A to 6E are cross-sectional views schematically showing a forming process of an accommodating part and the peripheral part thereof of the optical wiring substrate.

### DETAILED DESCRIPTION OF THE PREFERRED EMBODIMENTS

### Embodiment

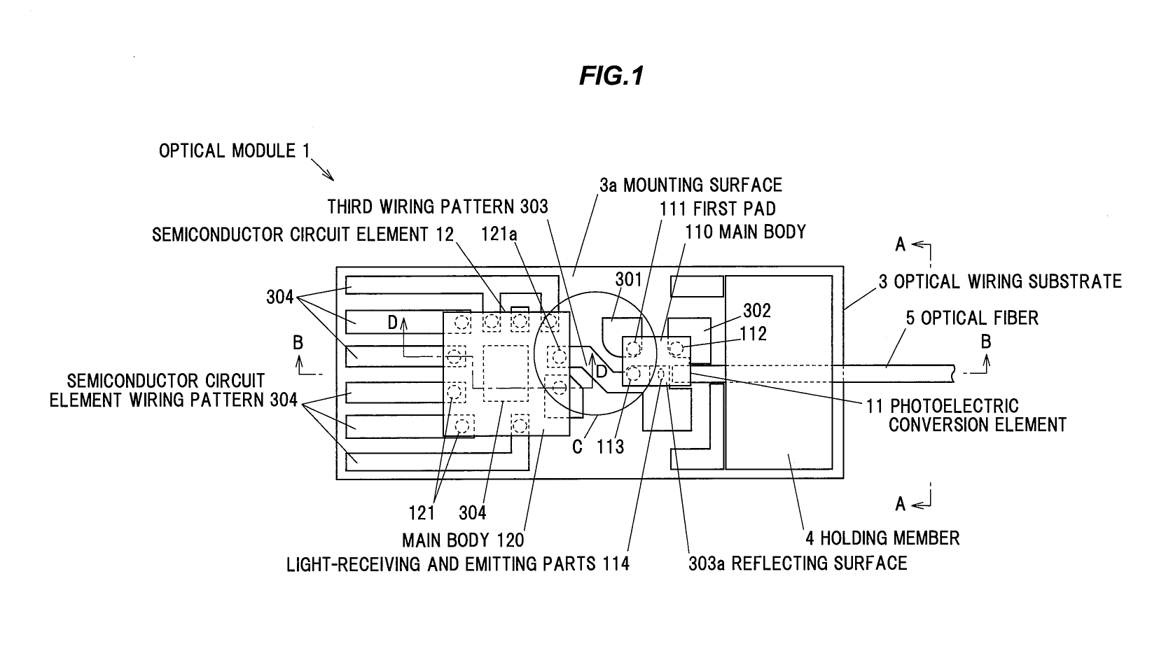

FIG. 1 is a plan view schematically showing a configuration example of an optical wiring substrate and an optical module including the optical wiring substrate according to an embodiment of the invention.

(Configuration of Optical Module 1)

The optical module 1 includes an optical wiring substrate 3, a photoelectric conversion element 11 mounted on a mounting surface 3a of the optical wiring substrate 3 by flip-chip mounting and a semiconductor circuit element 12 electrically connected to the photoelectric conversion element 11.

The photoelectric conversion element 11 is configured such that a first pad 111, a second pad 112 and a third pad 113 are disposed in a main body 110. Here, the pad means a copper foil configured to carry out soldering for mounting the components to be mounted on the surface of the substrate. The first pad 111 is electrically connected to a first wiring pattern 301 formed in the mounting surface 3a of the optical wiring substrate 3. The second pad 112 is electrically connected to a second wiring pattern 302 formed in the mounting surface 3a of the optical wiring substrate 3. The third pad 113 is electrically connected to a third wiring pattern 303 formed in the mounting surface 3a of the optical wiring substrate 3. In the third pad 113, a reflecting surface 303a configured to reflect a light that propagates the optical fiber 5 is formed. The photoelectric conversion element 11 is mounted above the reflecting surface 303a.

In the embodiment, the photoelectric conversion element 11 is configured such that the dimension in a direction parallel to the longitudinal direction of the optical fiber 5 is, for example, 350 μm, and the dimension in a direction perpendicular to the longitudinal direction of the optical fiber 5 is, for example, 250 μm.

The photoelectric conversion element 11 is an element configured to convert electric signals to optical signals or convert optical signals to electric signals. The former example includes a light emitting element such as a semiconductor laser element, a LED (Light Emitting Diode). In addition, the latter example includes a light receiving element such as a photo diode. The photoelectric conversion element 11 is configured to emit or receive a light from a light-receiving and emitting part 114 formed in the side of the mounting surface 3a of the optical wiring substrate 3 in a direction perpendicular to the optical wiring substrate 3.

The semiconductor circuit element 12 is mounted on the mounting surface 3a of the optical wiring substrate 3 by flip-chip mounting, and is configured such that a plurality (ten in the embodiment) of pad 121 are disposed in a main body 120. The plural pads 121 are electrically connected to the semiconductor circuit element wiring pattern 304 formed in the mounting surface 3a of the optical wiring substrate 3 respectively. Of the plural pads 121, a pad 121a configured to transmit signals is connected to the third wiring pattern 303 to which the third pad 113 of the photoelectric conversion element 11 is connected, thereby the semiconductor circuit element 12 and the photoelectric conversion element 11 are electrically connected to each other.

If the photoelectric conversion element 11 is configured to convert electric signals to optical signals, the semiconductor circuit element 12 is a driver IC configured to drive the photoelectric conversion element 11. If the photoelectric conversion element 11 is configured to convert optical signals to electric signals, the semiconductor circuit element 12 is a receiver IC configured to amplify signals input from the photoelectric conversion element 11.

Further, the optical wiring substrate 3 is configured such that electronic components, other than the photoelectric conversion element 11 and the semiconductor circuit element 12, such as a connector, an IC (Integrated Circuit), or an active element (a transistor and the like), a passive element (a resistor, a condenser and the like) are mounted thereon. In addition, a resin having heat conductivity can be filled between the electronic components and the optical wiring substrate 3. In this case, heat emitted from the electronic components becomes like to be conducted to the optical wiring substrate 3 via the resin.

The optical fiber 5 is arranged such that the end surface thereof faces the reflecting surface 303a formed in the third wiring pattern 303, and the optical fiber 5 is configured to be held by a holding member 4 from a position above the mounting surface 3a of the optical wiring substrate 3.

(Configuration of Optical Wiring Substrate 3)

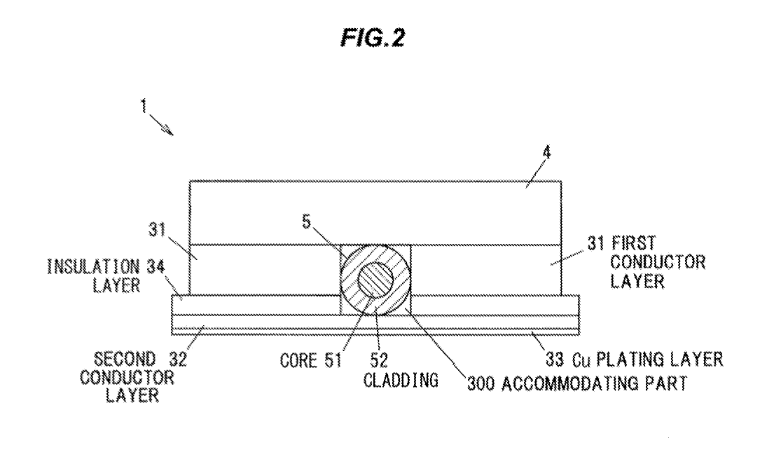

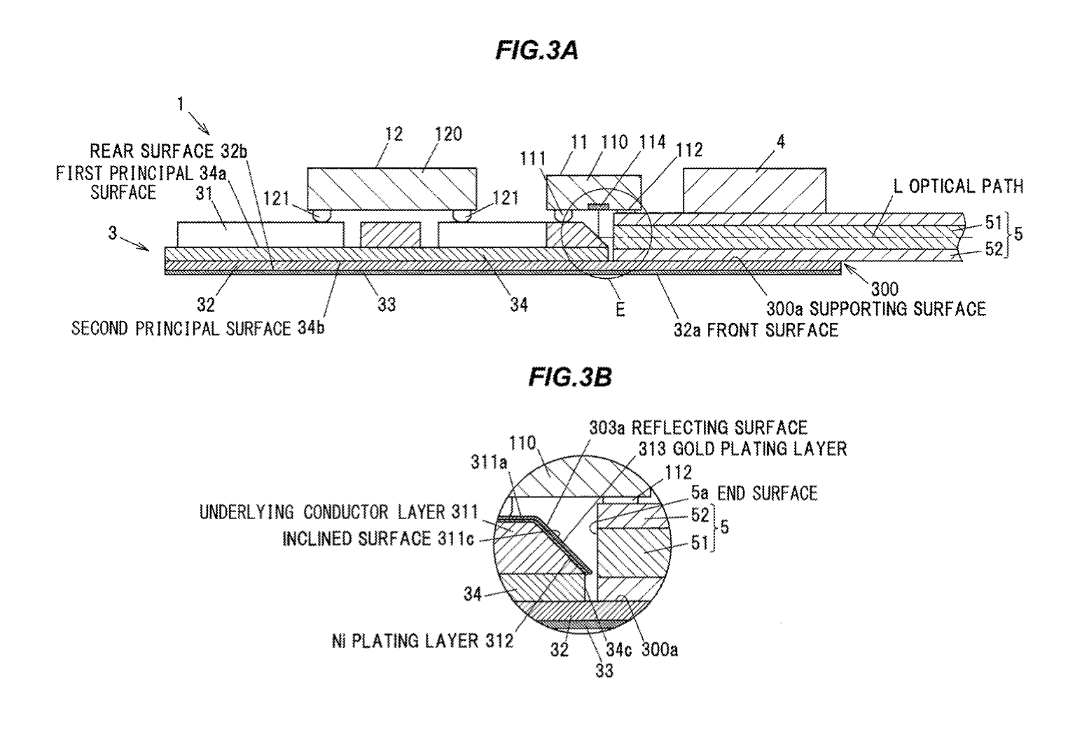

FIG. 2 is a cross-sectional view taken along the line A-A in FIG. 1. FIG. 3A is a cross-sectional view taken along the line B-B in FIG. 1, and FIG. 3B is a partial enlarged view of E part in FIG. 3A.

The optical fiber 5 includes the core 51 and the cladding 52. In the embodiment, the optical fiber 5 is configured such that the core 51 has a diameter of, for example, 50 μm, and the cladding 52 has a thickness in the radial direction of, for example, 37.5 μm. Namely, the optical fiber 5 has a diameter (a diameter obtained by summing the core 51 and the cladding 52) of 125 μm.

The optical wiring substrate 3 includes the first conductor layer 31 comprised of a resin, the second conductor layer 32 comprised of a metal arranged parallel to the first conductor layer 31, and the insulation layer configured to insulate between the first conductor layer 31 and the second conductor layer 32.

The first conductor layer 31 is configured such that, for example, a Ni plating layer 312 comprised of nickel (Ni) and a gold plating layer 313 comprised of gold (Au) are laminated on a front surface 311a of a underlying conductor layer 311 comprised of a good conductive metal such as copper. In the embodiment, the first conductor layer 31 has a thickness of, for example, 40 to 80 μm.

As shown in FIG. 3B, the Ni plating layer 25 and the gold plating layer 26 are also laminated on the surface of the inclined surface 311c formed in the underlying conductor layer 311. The reflecting surface 303a is formed on the outermost surface of the gold plating layer 313 in the inclined surface 311c.

In the first conductor layer 31, the above-mentioned first wiring pattern 301, the second wiring pattern 302, the third wiring pattern 303 and the semiconductor circuit element wiring pattern 304 are formed. The reflecting surface 303a (the inclined surface 311c) formed in a part of the third wiring pattern 303 is formed in a position facing a core 51 of the optical fiber 5.

As shown in FIG. 3A, when a light is emitted from the optical fiber 5 (the core 51), the reflecting surface 303a reflects the emitted light toward the photoelectric conversion element 11. If the photoelectric conversion element 11 is a light receiving element, the light reflected by the reflecting surface 303a enters the photoelectric conversion element 11 from the light-receiving and emitting part 114 disposed in the main body 110 of the photoelectric conversion element 11, and the photoelectric conversion element 11 converts light signals based on the incident light to electric signals.

In addition, if the photoelectric conversion element 11 is a light emitting element, the photoelectric conversion element 11 converts electric signals output from the semiconductor circuit element 12 to light signals, and emits the light exhibiting the light signals from the light-receiving and emitting part 114. The emitted light is reflected by the reflecting surface 303a toward the end surface 5a of the optical fiber 5 and enters the core 51 so as to propagate through the optical fiber 5. FIG. 3A shows the optical path L that uses the optical fiber 5 as a propagating medium of the light by an alternate long and short dash line.

The insulation layer 34 is comprised of, for example, a resin such as polyimide, and has a dimension in the thickness direction that is not less than 0.8 times and not more than 1.2 times relative to a thickness dimension of the cladding 52 of the optical fiber 5 in a radial direction. In the embodiment, the dimension of the insulation layer 34 in the thickness direction is, for example, 38 μm.

In the optical wiring substrate 3, an accommodating part 300 configured to extend along the longitudinal direction of the optical fiber 5 so as to accommodate at least a part of the optical fiber 5 is formed over the whole of the first conductor layer 31 and the insulation layer 34 in the thickness direction. In the insulation layer 34 in one end (end edge) of the accommodating part 300, an end surface 34c facing the cladding 52 of the optical fiber 5 is formed.

The second conductor layer 32 is, for example, comprised of a good conductive metal such as copper, and has a supporting surface 300a configured to support the optical fiber 5 accommodated in the accommodating part 300. More particularly, the accommodating part 300 passes through over the whole of the first conductor layer 31 and the insulation layer 33 in the thickness direction, and a rear surface 32b of the second conductor layer 32 is exposed. Accordingly, the rear surface 32b of the second conductor layer 32 is configured such that a part thereof is formed as the supporting surface 300a of the accommodating part 300. In addition, the second conductor layer 32 is configured such that a Cu plating layer 33 comprised of copper (Cu) is laminated on the front surface 32a. Further, similarly to the first conductor layer 31, wiring patterns can be also formed on the second conductor layer 32.

The accommodating part 300 is covered by the holding member 4 from a position above the first conductor layer 31 and the optical fiber 5 is fixed by an adhesive agent or the like that is filled in the accommodating part 300. In the embodiment, the cladding 52 of the optical fiber 5 is configured such that the peripheral surface thereof is in contact with the inner surface of the accommodating part 300.

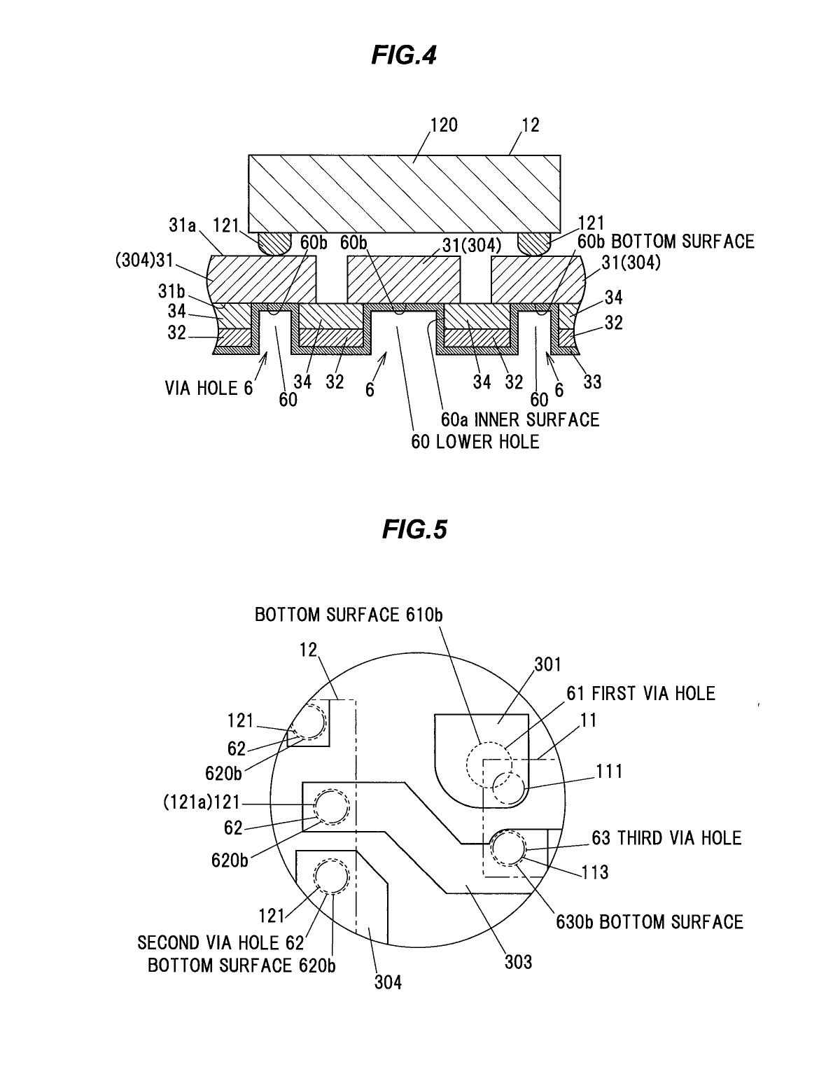

FIG. 4 is a cross-sectional view taken along the line D-D in FIG. 1. FIG. 5 is a partial enlarged view of C part in FIG. 1. FIG. 5 shows the outline of the photoelectric conversion element 11 and the semiconductor circuit element 12 by an alternate long and two short dashes line, and shows a plurality of the first via holes 61 by a broken line.

In the second conductor layer 32 an the insulation layer 34, a plurality of via holes 6 are formed so as to pass through the second conductor layer 32 and the insulation layer 34 in the thickness direction. In more particular, as shown in FIG. 4, the via holes 6 are configured to pass through the second conductor layer 32 and the insulation layer 34 in the thickness direction, to have lower holes 60 in which a bottom surface 60b blocked by the rear surface 31b of the first conductor layer 31 is formed, and to have inner surfaces 60a plated with a metal. Accordingly, the first conductor layer 31 is configured such that a part of the rear surface 31b is formed as the bottom surfaces 60b of the lower holes 60. In the embodiment, the inner surfaces 60a and the bottom surfaces 60b of the lower holes 60 are plated by the Cu plating layer 33 laminated on the front surface 32a of the second conductor layer 32.

The plural via holes 6 are configured such that at least a part of the bottom surface 60b is arranged in a plan view from the side of the mounting surface 3a of the optical wiring substrate 3 so as to overlap with an arrangement position of the pads (the first pad 111, the second pad 112 and the third pad 113) of the photoelectric conversion element 11 and the pads 121 of the semiconductor circuit element 12 that are mounted in the front surface 31a of the first conductor layer 31. Hereinafter, referring to FIG. 5, more particular explanation will be carried out. In FIG. 5, the explanation will be carried out by defining the via hole corresponding to the first pad 111 of the photoelectric conversion element 11 as a first via hole 61, the via hole corresponding to the pad 121 of the semiconductor circuit element 12 as a second via hole 62, and the via hole corresponding to the third pad 113 of the photoelectric conversion element 11 as a third via hole 63.

The first via hole 61 is arranged in a plan view from the side of the mounting surface 3a of the optical wiring substrate 3 such that a part of the bottom surface 610b overlaps with an arrangement position of the first pad 111 of the photoelectric conversion element 11 connected to the first wiring pattern 301. In more particular, when the optical wiring substrate 3 is seen through from the side of the front surface 31a of the first conductor layer 31, the bottom surface 610b of the first via hole 61 overlaps with a part of the first pad 111 of the photoelectric conversion element 11.

The third via hole 63 is arranged in a plan view from the side of the mounting surface 3a of the optical wiring substrate 3 such that the bottom surface 630b overlaps with an arrangement position of the third pad 113 of the photoelectric conversion element 11 connected to the third wiring pattern 303. In more particular, when the optical wiring substrate 3 is seen through from the side of the front surface 31a of the first conductor layer 31, the bottom surface 630b of the third via hole 63 overlaps with the whole of the third pad 113 of the photoelectric conversion element 11. Further, the third via hole 63 can be configured such that the bottom surface 630b overlaps with a part of the third pad 113 similarly to the first via hole 61.

A plurality (three in FIG. 5) of the second via holes 62 are respectively arranged in a plan view from the side of the mounting surface 3a of the optical wiring substrate 3 such that the bottom surfaces 620b overlap with arrangement positions of a plurality (three in FIG. 5) of the pads 121 of the semiconductor circuit element 12 connected to the semiconductor circuit element wiring pattern 304. In more particular, when the optical wiring substrate 3 is seen through from the side of the front surface 31a of the first conductor layer 31, the bottom surfaces 620b of the second via holes 62 overlap with the whole of the pads 121 of the semiconductor circuit element 12. Further, the second via hole 62 can be configured such that the bottom surface 620b overlaps with a part of the pad 121 similarly to the first via hole 61.

As shown in FIG. 4, any of the plural via holes 6 can be arranged in a plan view from the side of the mounting surface 3a of the optical wiring substrate 3 such that at least a part of the bottom surfaces 60b overlaps with an arrangement position of the main part 120 of the semiconductor circuit element 12. Thereby, heat emitted from the semiconductor circuit element 12 can be more efficiently conducted to the second conductor layer 32. Further, any of the plural via holes 6 is not limited to the configuration that at least a part of the bottom surfaces 60b overlaps with the arrangement position of the main part 120 of the semiconductor circuit element 12, but can be configured such that at least the part of the bottom surfaces 60b overlaps with arrangement positions of the main part 120 of the photoelectric conversion element 11 and the main parts of the other electronic components.

(Manufacturing Method of the Optical Wiring Substrate 3)

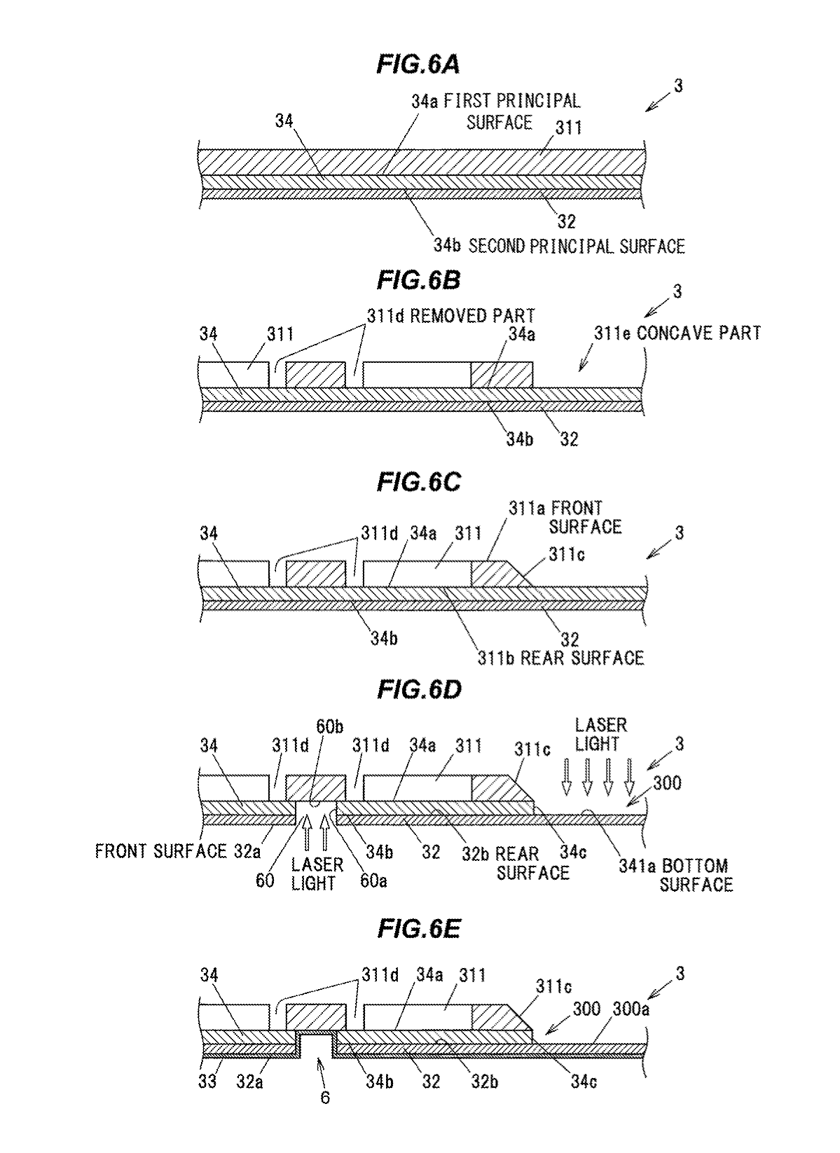

Next, a manufacturing method of the optical wiring substrate 3 will be explained referring to FIGS. 6A to 6E.

FIGS. 6A to 6E are cross-sectional views schematically showing a forming process of the accommodating part 300 and the peripheral part thereof of the optical wiring substrate 3.

The manufacturing process of the optical wiring substrate 3 includes a first step of forming the underlying conductor layer 311 on the first principal surface 34a of the insulation layer 34, and forming the second conductor layer 32 on the second principal surface 34b of the insulation layer 34, a second step of removing a part of the underlying conductor layer 311 so as to form wiring patterns (the first wiring pattern 301, the second wiring pattern 302, the third wiring pattern 303, and the semiconductor circuit element wiring pattern 304, and forming the concave part 311e that becomes the accommodating part 300, a third step of forming the inclined surface 311c in the underlying conductor layer 311, a fourth step of boring holes in the second conductor layer 32 and the insulation layer 34 over the whole thereof in the thickness direction up to the underlying conductor layer 311 (the first conductor layer 31) so as to form the lower holes 60, and removing the insulation layer 34 corresponding to the bottom surface of the concave part 311e over the whole thereof in the thickness direction up to the second conductor layer 32, thereby forming the accommodating part 300 and the end surface 34c, a fifth step of forming the Cu plating layer 33 on the front surface 32a of the second conductor layer 32 and the inner surfaces 60a of the lower holes 60, and a sixth step of laminate the Ni plating layer 312 and the gold plating layer 313 on the front surface 311a of the underlying conductor layer 311, the rear surface 32b of the second conductor layer 32 and the inclined surface 311c. Hereinafter, the first to sixth steps will be explained in more detail.

As shown in FIG. 6A, in the first step, the underlying conductor layer 311 is respectively formed on the whole of the first principal surface 34a of the insulation layer 34, and the second conductor layer 32 is formed on the whole of the second principal surface 34b of the insulation layer 34, for example, by adhesion, vapor deposition, or non-electroless plating. In the embodiment, the underlying conductor layer 311 and the second conductor layer 32 are comprised of copper (Cu) as a main component that has a good electrical conductivity.

As shown in FIG. 6B, in the second step, a part of the underlying conductor layer 311 is removed by etching so as to respectively form the first wiring pattern 301, the second wiring pattern 302, the third wiring pattern 303, and the semiconductor circuit element wiring pattern 304, and forming the concave part 311e that becomes the accommodating part 300. In more particular, regions of the underlying conductor layer 311 except for a part corresponding to the removed part 311d and a part corresponding to the concave part 311e with a resist, and a part of the underlying conductor layer 311 which is not coated with the resist is dissolved by etching. Thereby, the underlying conductor layer 311 corresponding to the removed part 311d and the concave part 311e is dissolved so as to leave only the underlying conductor layer 311 corresponding to the first wiring pattern 301, the second wiring pattern 302, the third wiring pattern 303 and the semiconductor circuit element wiring pattern 304.

Further, in the step, similarly to the underlying conductor layer 311, a part of the second conductor layer 32 may be removed by etching so as to form wiring patterns in the second conductor layer 32.

As shown in FIG. 6C, in the third step, the underlying conductor layer 311 is cut obliquely to the insulation layer 34 from the front surface 311a to rear surface 311b of the underlying conductor layer 311, thereby the inclined surface 311c is formed.

As shown in FIG. 6D, in the fourth step, a laser light is irradiated from a perpendicular direction to the front surface 32a of the second conductor layer 32. As the laser light, more particularly, for example, an excimer laser or an UV laser (ultraviolet laser) can be used. By the irradiation of the laser light, the second conductor layer 32 and the insulation layer 34 are bored in the thickness direction so as to form the lower hole 60. In the embodiment, by adjusting the irradiation time of the laser light, only the second conductor layer 32 and the insulation layer 34 can be cut by the irradiation of the light. Accordingly, the rear surface 311b of the underlying conductor layer 311 is configured such that a part thereof exposed by the irradiation of the laser light is formed as the bottom surface 60b that blocks the one end of the lower hole 60.

In addition, in the fourth step, a laser light is irradiated from a perpendicular direction to the first principal surface 34a of the insulation layer 34 corresponding to the bottom surface of the concave part 311e. Thereby, the accommodating part 300 that accommodates the optical fiber 5 is formed, and the end surface 34c in the end edge of the accommodating part 300 is formed in the insulation layer 34. The intensity of the laser light is an intensity that the insulation layer 34 can be cut but the underlying conductor layer 311 and the second conductor layer 32 cannot be cut by the irradiation of the light. Accordingly, a part of the rear surface 32b of the second conductor layer 32 that is exposed by the irradiation of the laser light is formed as the supporting surface 300a of the accommodating part 300. In the embodiment, the end surface 34c is formed to be perpendicular to the supporting surface 300a of the accommodating part 300 (the rear surface 32b of the second conductor layer 32), and functions as an abutting surface for positioning when the optical fiber 5 is inserted into the accommodating part 300.

As shown in FIG. 6E, in the fifth step, the Cu plating layer 33 is formed on the whole of the front surface 32a of the second conductor layer 32 and the inner surface 60a of the lower hole 60, for example, by adhesion, vapor deposition, or electroless plating.

In the sixth step, plating of nickel (Ni) and gold (Au) is applied to the front surface 311a of the underlying conductor layer 311, the inclined surface 311c and the front surface 32a of the second conductor layer 32 so as to form the Ni plating layer 312 and the gold plating layer 313. The nickel (Ni) plating and the gold (Au) plating can be carried out by, for example, electroless plating. The reflecting surface 303a is formed on the outermost surface of the gold plating layer 313.

### Operation and Advantage of the Second Embodiment

According to the above-mentioned embodiment, the following operation and advantage can be obtained.

The via holes 6 formed in the optical wiring substrate 3 are configured such that at least a part of the bottom surface 60b is arranged in a plan view from the side of the mounting surface 3a of the optical wiring substrate 3 so as to overlap with arrangement positions of the pads (the first pad 111, the second pad 112 and the third pad 113) of the photoelectric conversion element 11 and the pads 121 of the semiconductor circuit element 12 that are mounted in the first conductor layer 31, thus heat emitted from the photoelectric conversion element 11 and the semiconductor circuit element 12 can be conducted to the second conductor layer 32 via the via holes 6 so as to be radiated. In addition, by intervention of the via holes 6, the arrangement of wiring can be easily carried out.

### Summary of the Embodiments

Next, the technical idea grasped from the above-explained embodiments will be described by utilizing the reference numerals and the like in the embodiments. However, the respective reference numerals and the like in the following description do not limit the constitutional components in the scope of the claim to the members concretely shown in the embodiments.

[1] An optical wiring substrate (3) in which electronic components including a photoelectric conversion element (11) are mounted, comprising a first conductor layer (31) comprised of a metal, a second conductor layer (32) comprised of a metal arranged parallel to the first conductor layer (31), and an insulation layer (34) configured to insulate between the first conductor layer (31) and the second conductor layer (32), wherein via holes (6) of which inner surface (60a) is plated with a metal (Cu plating layer 33) are formed in the second conductor layer (32) and the insulation layer (34) so as to pass through the second conductor layer (32) and the insulation layer (34) in the thickness direction, and the via holes (6) are configured such that at least a part of the bottom surface (60b) blocked by the first conductor layer (31) is arranged in planar view so as to overlap with arrangement positions of the pads of the electronic components that are mounted in the first conductor layer (31).

[2] The optical wiring substrate (3) according to [1], wherein the via holes (6) are configured such that at least a part of the bottom surface (60b) is arranged in planar view so as to overlap with arrangement positions of the pads (the first pad 111, the second pad 112 and the third pad 113) of the photoelectric conversion element (11).

[3] An optical module, comprising the optical wiring substrate (3) according to [1] or [2], and the electronic components.

[4] A manufacturing method of the optical wiring substrate (3) according to [1] or [2], comprising the first step of forming the first conductor layer (31) on the first principal surface (34a) of the insulation layer (34), and forming the second conductor layer (32) on the second principal surface (34b) of the insulation layer (34), the second step of removing a part of the first conductor layer (31) so as to form wiring patterns (the first wiring pattern 301, the second wiring pattern 303, the third wiring pattern 303 and the semiconductor circuit element wiring pattern 304), the third step of boring holes in the second conductor layer (32) and the insulation layer (34) over the whole thereof in the thickness direction up to the first conductor layer (31), and the fourth step of forming the plating layer (the Cu plating layer 33) on the inner surface (60a) of the holes (the lower holes 60) formed in the third step and the front surface (32a) of the second conductor layer (32).

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

For example, in the above-mentioned embodiments, a configuration that only one accommodating part 300 and only one optical module 1 are formed in the optical wiring substrate 3 has been explained, but not limited to this, a plurality of accommodating parts 300 and a plurality of optical module structures may be formed in the optical wiring substrate 3.

In addition, in the above-mentioned embodiments, a configuration that the underlying conductor layer 311 of the first conductor layer 31 and the second conductor layer 32 are comprised of copper (Cu) has been explained, but not limited to this, a part or the whole of the underlying conductor layer 311 of the first conductor layer 31 and the second conductor layer 32 may be comprised of, for example, aluminum (Al). Also, materials of the plating layers are not limited to the above-mentioned materials. Materials of the insulation layer 34 are not limited to polyimide, but, for example, polyethylene terephthalate (PET) may be also used.

In addition, in the above-mentioned embodiments, a configuration that the lower holes 60 and the accommodating part 300 are formed by using a laser light has been explained, but not limited to this, those may be formed by a shadow mask configured such that the transmitted light is adjusted or a mechanical processing such as dicing. In case of the mechanical processing, the lower holes 60 and the accommodation part 300 can be formed at lower cost than the processing by the laser light.

In addition, in the above-mentioned embodiments, a configuration that the second via hole 62 is formed at only the position below the semiconductor circuit element 12, but not limited to this, the second via hole 62 may be also formed at the position below the photoelectric conversion element 11 and the other electronic components (not shown).

In addition, the second via hole 62 may be a through hole passing through the whole of the first conductor layer 31, the insulation layer 34 and the second conductor layer 32 in the thickness direction.

What is claimed is:

1. An optical wiring substrate, comprising:
a first conductor layer comprising a metal;
a second conductor layer comprising a metal and arranged parallel to the first conductor layer;
an insulation layer disposed to insulate the first conductor layer from the second conductor layer; and
an electronic component including a photoelectric conversion element mounted on the substrate; and
a via hole formed in the second conductor layer and the insulation layer so as to pass through the second conductor layer and the insulation layer in a thickness direction thereof, the via hole comprising an inner surface plated with a metal,
wherein the via hole is configured such that at least a part of a bottom surface thereof blocked by the first conductor layer is arranged in a plan view so as to overlap with an arrangement position of a pad of the electronic component that is mounted on the first conductor layer.

2. The optical wiring substrate according to claim 1, wherein the via hole is configured such that at least a part of the bottom surface is arranged in a plan view so as to overlap with an arrangement position of a pad of the photoelectric conversion element.

3. An optical module, comprising:
the optical wiring substrate according to claim 1; and
the electronic component.

4. A manufacturing method of the optical wiring substrate according to claim 1, comprising:
forming the first conductor layer on a first principal surface of the insulation layer, and forming the second conductor layer on a second principal surface of the insulation layer;
removing a part of the first conductor layer so as to form a wiring pattern;
making a hole in the second conductor layer and the insulation layer over a whole thereof in a thickness direction so as to reach the first conductor layer; and
forming a plating layer on the inner surface of the hole made in the making of the hole and a front surface of the second conductor layer.
